(19) United States
(12) Patent Application Publication
(10) Pub. No.: US 2026/0026085 A1
(43) Pub. Date: Jan. 22, 2026

(54) Resistor Structure of a Semiconductor Device and A Semiconductor Device including the same

(71) Applicant: LX SEMICON CO., LTD., Daejeon (KR)

(72) Inventors: Si Won LEE, Daejeon (KR); Byoung Chul PARK, Daejeon (KR); Nam Jin KIM, Daejeon (KR)

(73) Assignee: LX SEMICON CO., LTD., Daejeon (KR)

(21) Appl. No.: 19/269,801

(22) Filed: Jul. 15, 2025

(30) Foreign Application Priority Data
Jul. 16, 2024 (KR) 10-2024-0093627

(51) Int. Cl. H10D 84/80; H10D 1/00; H10D 1/47; H10D 84/01

(52) U.S. Cl. CPC H10D 84/817; H10D 1/47; H10D 1/021; H10D 84/01

(57) ABSTRACT

The resistor structure of the semiconductor device according to the embodiment may include a semiconductor substrate including a device semiconductor layer and a resistor semiconductor layer, a first isolation region of device and a second isolation region of device respectively disposed on the device semiconductor layer and the resistor semiconductor layer, and a register poly layer disposed on a first register trench from which a portion of the second isolation region of device is removed.

### CROSS-REFERENCE TO RELATED APPLICATIONS

The present application claims the benefit of priority of Korean Patent Application No. 10-2024-0093627, filed on Jul. 16, 2024, which is hereby incorporated by reference in its entirety.

### BACKGROUND

### Field of the Disclosure

The embodiment relates to a resistor structure of a semiconductor device, a semiconductor device including the same, and a method for manufacturing the same. For example, the embodiment relates to a poly resistor structure of a semiconductor device, a semiconductor device including the same, and a method for manufacturing the same.

### Description of the Background

An integrated circuit device is a functional device that has a complete circuit function by integrating a large number of active and passive devices into a single semiconductor substrate in an ultra-small size and has an inseparable structure, and is used in various industrial fields.

These integrated circuit devices are circuit devices in which transistors, diodes, capacitors, and resistors are densely integrated, and various sizes of resistance are required depending on a purpose of the electronic device in which the integrated circuit devices are used.

Since the resistance device requires greater resistance than the wiring structure of the integrated circuit device, the resistance device is generally formed on the device isolation film while forming the gate structure of the transistor in the active area of the semiconductor substrate. For example, since polysilicon, a material used in the manufacturing process of semiconductor devices, may be doped with various impurities to control resistance, the gate electrode of the transistor and the resistance device may be formed simultaneously using polysilicon.

On the other hand, since the resistance is proportional to a length of polysilicon, a certain length must be secured in order to implement a high-resistance poly resistor. For example, in the prior art, a poly resistor structure with a length of about 1.4 μm and a thickness of about 0.2 μm was inevitably required to implement a high-resistance poly resistor.

Accordingly, in the prior art, there is a problem of a technical contradiction that it is difficult to implement ultra-miniaturization of semiconductor devices in order to implement a high-resistance poly resistor.

### SUMMARY

Accordingly, the present disclosure is directed to a resistor structure of a semiconductor device, a semiconductor device including the same, and a method for manufacturing the same that substantially obviate one or more of problems due to limitations and disadvantages described above.

One of the technical problems of the embodiment is to solve a technical problem that it is difficult to implement ultra-miniaturization of semiconductor devices when implementing a high-resistance poly resistor. The technical problems of the embodiment are not limited to those described in this item, and include those understood from the description of the invention.

The resistive device structure of the semiconductor device according to the embodiment may include a semiconductor substrate including a device semiconductor layer (110) and a resistor semiconductor layer (210), a first isolation region of device (120) and a second isolation region of device (220) respectively disposed on the device semiconductor layer (110) and the resistor semiconductor layer (210), and a register poly layer (240) disposed on a first register trench (RT1) from which a portion of the second isolation region of device (220) is removed.

In addition, the embodiment may further include a register insulating layer (230) disposed under the register poly layer (240) on the first register trench (RT1).

The register poly layer (240) may include a trench poly layer (242) disposed inside the first register trench (RT1) and first and second poly layers (241, 243) disposed on the second isolation region of device (220), respectively.

The first depth (L1) of the first register trench (RT1) may be at least ½ of the depth (L) of the second isolation region of device (220).

The register poly layer (240) may include a register ion implantation region (270).

The register ion implantation region (270) may be in contact with the register insulating layer (230).

In addition, wherein a horizontal width of the second isolation region of device may be greater than a horizontal width of the first isolation region of device.

In addition, wherein a depth of the first isolation region of device may be the same with that of the second isolation region of device.

In addition, wherein a material of the register insulating layer may be the same with that of a gate insulating layer.

In addition, the resistor insulating layer may be spaced apart from the resistor semiconductor layer.

In addition, the resistor structure of the semiconductor device according to the embodiment may include a semiconductor substrate including a device semiconductor layer (110) and a resistor semiconductor layer (210), a first isolation region of device (120) and a second isolation region of device (220) respectively disposed on the device semiconductor layer (110) and the resistor semiconductor layer (210), a resistor insulating layer (230) disposed on a second register trench (RT2) from which a part of the second isolation region of device (220) is removed to expose a part of the resistor semiconductor layer (210), and a resistor poly layer (240) disposed on the resistor insulating layer (230).

The resistor poly layer (240) may include a trench poly layer (242) disposed inside the second register trench (RT2) and first and second poly layers (241, 243) respectively disposed on the second isolation region of device (220).

The second depth (L2) of the second register trench (RT2) may be equal to the depth (L) of the second isolation region of device (220).

The register poly layer (240) may include a register ion implantation region (270).

The register ion implantation region (270) may be in contact with the register insulating layer (230).

In addition, a horizontal width of the second isolation region of device may be greater than a horizontal width of the first isolation region of device.

In addition, wherein a depth of the first isolation region of device may be the same with that of the second isolation region of device.

In addition, wherein a material of the register insulating layer may be the same with that of a gate insulating layer.

In addition, wherein a second depth of the second register trench may be greater than a thickness of the second isolation region of device.

In addition, the semiconductor device according to the embodiment may include a resistance device structure of any one of the semiconductor devices.

According to the embodiment, there is a technical effect of implementing a high-resistance poly resistor while enabling the implementation of ultra-fine semiconductor devices.

For example, according to an embodiment, after forming a first register trench (RT1) to a depth of at least ½ of the depth (L) of the second isolation region of device (220), a register insulating layer (230) and a register poly layer (240) may be formed on the first register trench (RT1) (see FIG. 1A and FIG. 1B).

Accordingly, according to an embodiment, by forming a register poly layer (240) on the first register trench (RT1) formed to a depth of at least ½ of the depth (L) of the second isolation region of device (220), the length of the register poly layer (240) can be maximized without expanding a size of the semiconductor device. Accordingly, there is a technical effect of implementing a high-resistance poly register while enabling the implementation of ultra-fine semiconductor devices.

In addition, according to the embodiment, after forming the first register trench (RT1), a surface roughness of the first register trench (RT1) can be improved by the process of forming the register insulating layer (230), thereby preventing occurrence of roughness in the register poly layer (240) formed thereafter, thereby providing a technical effect of securing a stable resistance value of the resistor device.

In addition, according to the second embodiment, after etching so that a part of the register semiconductor layer (210B) is exposed by the second register trench (RT2), the register insulating layer (230) and the register poly layer (240) may be formed on the second register trench (RT2) (see FIG. 2A and FIG. 2B).

Accordingly, according to the second embodiment, after forming a register insulating layer (230) on a second register trench (RT2) formed to a depth deep enough to expose a portion of a register semiconductor layer (210B), a register poly layer (240) may be formed on the register insulating layer (230).

According to the second embodiment, the length of the register poly layer (240) can be maximized without causing an electrical short circuit due to the register insulating layer (230). Accordingly, there is a special technical effect that enables the implementation of ultra-fine semiconductor devices while implementing a high-resistance poly register.

In addition, according to the embodiment, when forming a poly register pattern having the same resistance length, there is an effect that can reduce the chip area of the semiconductor device when applying the present embodiment.

The technical effects of the embodiment are not limited to those described in this item, and include those understood from the description of the invention.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1A is a cross-sectional view of a semiconductor device (1001) including a poly register structure according to the first embodiment.

FIG. 1B is a cross-sectional view of a part of a manufacturing process of a semiconductor device (1001) including a poly register structure according to the first embodiment.

FIG. 2A is a cross-sectional view of a semiconductor device (1002) including a poly register structure according to the second embodiment.

FIG. 2B is a cross-sectional view of a part of a manufacturing process of a semiconductor device (1002) including a poly register structure according to the second embodiment.

FIGS. 3 to 8 are cross-sectional views of a manufacturing process of a semiconductor device including a poly register structure according to the embodiment.

### DETAILED DESCRIPTION

Hereinafter, the aspects disclosed in this specification will be described in detail with reference to the attached drawings. The suffixes ‘module’ and ‘part’ used for elements in the following description are given or used interchangeably in consideration of the ease of writing the specification, and do not have distinct meanings or roles in themselves. In addition, the attached drawings are intended to facilitate easy understanding of the aspects disclosed in this specification, and the technical ideas disclosed in this specification are not limited by the attached drawings. In addition, when an element such as a layer, region, or substrate is mentioned as existing ‘on’ another element, this includes that it may be directly on the other element, or that other intermediate elements may exist in between.

In the specification or claims, the meaning of “an element A includes at least one of a, b, and/or c” may include \textcircled{1} when the element A includes the element a, \textcircled{2} when the element A includes the element b, \textcircled{3} when the element A includes the element c, \textcircled{4} when the element A includes the elements a and b, \textcircled{5} when the element A includes the elements b and c, \textcircled{6} when the element A includes the elements a and c, and \textcircled{7} when the element A includes all elements of a, b, and c.

The singular expression includes the plural expression as well as the singular expression, unless the context clearly indicates otherwise. For example, the meaning of “element A includes one structure” may include the meaning of “element A includes one or more structures.”

### EMBODIMENT

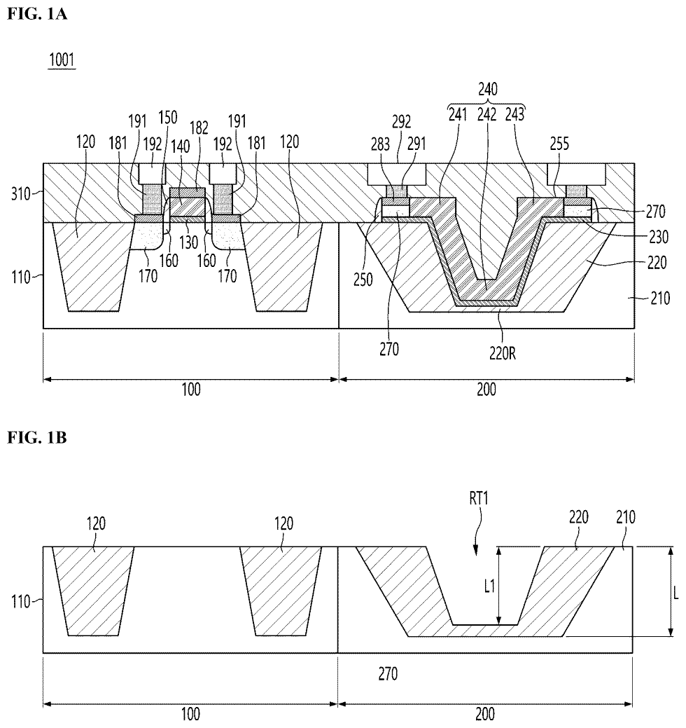

FIG. 1A is a cross-sectional view of a semiconductor device (1001) including a poly resistor structure according to the first embodiment. FIG. 1B is a cross-sectional view of a part of a manufacturing process of a semiconductor device (1001) including a poly resistor structure according to the first embodiment. Hereinafter, ‘first embodiment’ may be abbreviated as ‘example’.

A semiconductor device (1001) including a poly register structure according to the first embodiment may include a semiconductor substrate including a device semiconductor layer (110) and a register semiconductor layer (210).

The device semiconductor layer (110) may be a semiconductor layer on which an active device such as a transistor is formed, and the register semiconductor layer (210) may be a semiconductor layer on which a passive device such as a resistor is formed.

In addition, the embodiment may include a first isolation region of device (120) and a second isolation region of device (220) respectively disposed on the device semiconductor layer (110) and the register semiconductor layer (210) of the semiconductor substrate.

A horizontal width of the second isolation region of device (220) may be greater than a horizontal width of the first isolation region of device (120), but is not limited thereto.

In addition, depths of the first isolation region of device (120) and the second isolation region of device (220) may be the same, but are not limited thereto.

For example, the first isolation region of device (120) and the second isolation region of device (220) may be formed with a predetermined depth (L), but are not limited thereto.

For example, referring to FIG. 1B, the embodiment may include a first register trench (RT1) formed by partially removing the second isolation region of device (220).

In the first embodiment, a first depth (L1) of the first register trench (RT1) may be at least ½ of a depth (L) of the second isolation region of device (220).

Referring again to FIG. 1A, the embodiment may form the first register trench (RT1) at least ½ of the depth (L) of the second isolation region of device (220), and then form a register insulating layer (230) and a register poly layer (240) on the first register trench (RT1).

Accordingly, according to the embodiment, by forming the register poly layer (240) on the first register trench (RT1) formed with a depth of at least half the depth (L) of the second isolation region of device (220), the length of the register poly layer (240) can be maximized without expanding the size of the semiconductor device, and thus, there is a technical effect of implementing a high-resistance poly register while enabling the implementation of ultra-fine semiconductor devices.

Meanwhile, according to internal research, it has been studied that the surface of the first register trench (RT1) may be roughened by the process of forming the first register trench (RT1) by etching the second isolation region of device (220) with a deep depth. The problem that the roughness may be transmitted to the register poly layer (240) formed later and causes resistance variation of the resistance device has been studied.

According to the embodiment, after forming the first register trench (RT1), the surface roughness of the first register trench (RT1) can be improved by the process of forming the register insulating layer (230). Accordingly, there is a technical effect of preventing occurrence of roughness in the register poly layer (240) formed thereafter, thereby securing a stable resistance value of the resistance device.

In addition, the embodiment may include a gate insulating layer (130) and a gate electrode (140) disposed on the device semiconductor layer (110) located between the first isolation region of devices (120).

The gate insulating layer (130) may be formed of a thermal oxide layer or a deposition oxide layer, but is not limited thereto. The gate electrode (140) may be formed of polysilicon, but is not limited thereto.

In addition, the embodiment may form a register insulating layer (230) and a register poly layer (240) on the first register trench (RT1) of the register semiconductor layer (210). The register insulating layer (230) may be formed of the same material as the gate insulating layer (130), but is not limited thereto.

The register poly layer (240) may include a trench poly layer (242) disposed inside the first register trench (RT1) and first and second poly layers (241, 243) disposed on the second isolation region of device (220), respectively.

In addition, the embodiment may include a first ion implantation region (160) on the device semiconductor layer (110) on both sides of the gate electrode (140).

The device semiconductor layer (110) may be formed as an N-MOS region or a P-MOS region.

For example, after forming a p-type well (not shown) in the device semiconductor layer (110), an n-type dopant may be ion-implanted into the p-type well to form a first ion implantation region (160). At this time, LDD ion implantation may also be performed on the register poly layer (240).

In addition, the embodiment may include a first spacer (150) disposed on the gate electrode (140) side of the device semiconductor layer (110), and a source region (170) and a drain region (170) formed on the device semiconductor layer (110).

In addition, the embodiment may include a second spacer (250) and a third resistor insulating layer (255) in the register poly layer (240) on the resistor semiconductor layer (210), and a resistor ion implantation region (270) formed in a predetermined second ion implantation (SD).

For example, the second spacer (250) may be formed on the first and second poly layers (241, 243) of the register poly layer (240), and a third register insulating layer (255) may be formed on the trench poly layer (242), after which a register ion implantation region (270) may be formed on the first and second poly layers (241, 243) by a second ion implantation (SD) (See FIG. 7).

In addition, the embodiment may include a first silicide (181) disposed on the source region (170) and the drain region (170) of the device region, and a second silicide (182) disposed on the gate electrode (140). In addition, a third silicide (283) may be formed on the register ion implantation region (270) of the register poly layer (240). The first to third silicides (181, 182, 283) may be, but are not limited to, NiSi or CoSi₂.

In addition, after the interlayer insulating layer (310) is formed, an open process is performed to remove a portion of the interlayer insulating layer, and a first wiring (191) and a first metal electrode (192) may be sequentially formed on the exposed first silicide (181). In addition, a second wiring (not shown) and a second metal electrode (not shown) may be sequentially formed on the second silicide (182). In addition, a third wiring (291) and a third metal electrode (292) may be sequentially formed on the third silicide (283).

According to the embodiment, there is a technical effect that enables the implementation of ultra-fine semiconductor devices while implementing a high-resistance poly resistor.

For example, according to an embodiment, after forming a first register trench (RT1) to a depth of at least ½ of the depth (L) of the second isolation region of device (220), the register insulating layer (230) and the register poly layer (240) may be formed on the first register trench (RT1) (see FIG. 1A and FIG. 1B).

Accordingly, according to an embodiment, by forming a register poly layer (240) on the first register trench (RT1) formed to a depth of at least ½ of the depth (L) of the second isolation region of device (220), the length of the register poly layer (240) can be maximized without expanding the size of the semiconductor device, and accordingly, there is a technical effect that enables the implementation of ultra-fine semiconductor devices while implementing a high-resistance poly resistor.

In addition, according to the embodiment, after forming the first register trench (RT1), the surface of the first register trench (RT1) can be improved in roughness by the process of forming the register insulating layer (230), thereby preventing occurrence of roughness in the register poly layer (240) formed thereafter, thereby providing a technical effect of securing a stable resistance value of the resistor device.

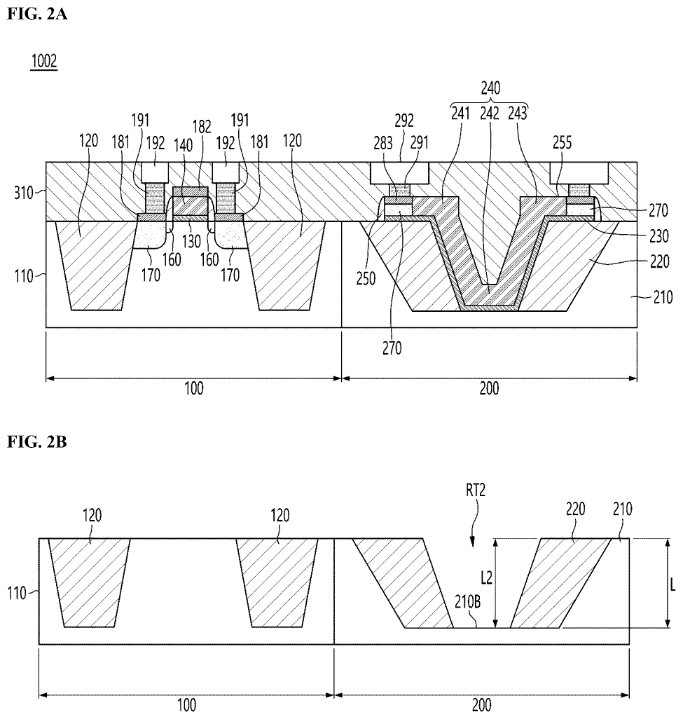

Next, FIG. 2A is a cross-sectional view of a semiconductor device (1002) including a poly register structure according to the second embodiment. FIG. 2B is a cross-sectional view of a part of a manufacturing process of a semiconductor device (1001) including a poly register structure according to the second embodiment.

The second embodiment can adopt the technical features of the first embodiment, and the main features of the second embodiment will be described below.

First, referring to FIG. 2B, in the second embodiment, after etching so that a part of the register semiconductor layer (210B) is exposed by the second register trench (RT2), a register insulating layer (230) and a register poly layer (240) may be formed on the second register trench (RT2) (see FIG. 2A).

Accordingly, according to the second embodiment, after forming the register insulating layer (230) on the second register trench (RT2) formed to a depth deep enough to expose a part of the register semiconductor layer (210B), a register poly layer (240) may be formed on the register insulating layer (230).

According to the second embodiment, the length of the register poly layer (240) can be maximized without causing an electrical short circuit by the register insulating layer (230). Accordingly, there is a special technical effect that enables the implementation of a high-resistance poly resistor while also enabling the implementation of ultra-fine semiconductor devices.

Meanwhile, the surface of the second register trench (RT2) may be roughened by the process of forming the second register trench (RT2) by etching the second isolation region of device (220) to a deep depth, and the problem that the roughness is transmitted to the register poly layer (240) formed later and causes resistance fluctuation of the resistance device has been studied.

According to an embodiment, after forming the second register trench (RT2), the roughness of the surface of the second register trench (RT2) can be improved by the process of forming the register insulating layer (230), and thus, the occurrence of roughness in the register poly layer (240) formed later can be prevented, thereby providing a special technical effect that enables the stable resistance value of the resistance device to be secured.

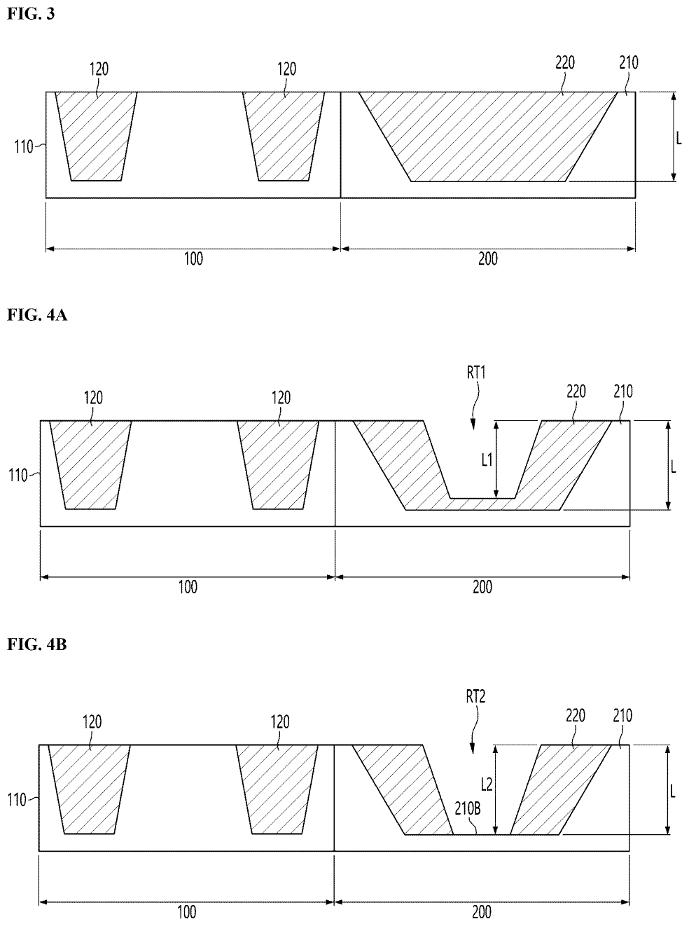

FIGS. 3 to 8 are cross-sectional views of a manufacturing process of a semiconductor device including a poly resistor structure according to an embodiment.

First, referring to FIG. 3, a predetermined semiconductor substrate may be prepared. The semiconductor substrate may include a device semiconductor layer (110) and a resistor semiconductor layer (210). For example, the semiconductor substrate may include a device semiconductor layer (110) and a resistor semiconductor layer (210), but is not limited thereto. The device semiconductor layer (110) may be a semiconductor layer on which an active device such as a transistor is formed, and the resistor semiconductor layer (210) may be a semiconductor layer on which a passive device such as a resistor device is formed.

A first isolation region of device (120) and a second isolation region of device (220) may be formed on the device semiconductor layer (110) and the resistor semiconductor layer (210) of the semiconductor substrate, respectively.

The first isolation region of device (120) and the second isolation region of device (220) may form a STI (Shallow Trench Isolation), but is not limited thereto.

For example, a first trench (not shown) and a second trench (not shown) may be formed by removing a portion of the device semiconductor layer (110) and the register semiconductor layer (210), respectively, and then the first trench and the second trench may be deposited with an oxide layer or the like to form the first isolation region of device (120) and the second isolation region of device (220), but it is not limited thereto.

The horizontal width of the second isolation region of device (220) may be greater than the horizontal width of the first isolation region of device (120), but it is not limited thereto.

The depths of the first isolation region of device (120) and the second isolation region of device (220) may be the same, but it is not limited thereto.

For example, the first isolation region of device (120) and the second isolation region of device (220) may be formed with a predetermined depth (L), but it is not limited thereto.

Next, referring to FIG. 4A, a portion of the second isolation region of device (220) may be removed to form a first register trench (RT1). FIG. 4A may correspond to the first embodiment (1001) illustrated in FIG. 1.

In the first embodiment, the first depth (L1) of the first register trench (RT1) may be at least ½ of the depth (L) of the second isolation region of device (220).

According to the embodiment, after the first register trench (RT1) is formed to at least ½ of the depth (L) of the second isolation region of device (220), a register insulating layer (230) and a register poly layer (240) may be formed on the first register trench (RT1) (see FIG. 1A).

Accordingly, according to the embodiment, by forming the register poly layer (240) on the first register trench (RT1) formed with a depth of at least ½ of the depth (L) of the second isolation region of device (220), the length of the register poly layer (240) can be maximized without expanding the size of the semiconductor device, and thus, there is a technical effect of implementing a high-resistance poly register while enabling the implementation of ultra-fine semiconductor devices.

Meanwhile, according to an internal study, the surface of the first register trench (RT1) may be roughened by the process of forming the first register trench (RT1) by etching the second isolation region of device (220) with a deep depth, and the problem of the roughness being transmitted to the register poly layer (240) formed later, causing a change in the resistance of the resistor device, has been studied.

According to the embodiment, after forming the first register trench (RT1), the surface of the first register trench (RT1) can be improved in roughness by the process of forming the register insulating layer (230), thereby preventing the occurrence of roughness in the register poly layer (240) formed thereafter, thereby providing a technical effect of securing a stable resistance value of the resistor device.

Next, referring to FIG. 4B, the second isolation region of device (220) may be partially removed to form the second register trench (RT2). FIG. 4B may correspond to the second embodiment illustrated in FIG. 2A.

In the second embodiment, the second depth (L2) of the second register trench (RT2) may be equal to the depth (L) of the second isolation region of device (220).

In the second embodiment, a part of the register semiconductor layer (210B) may be exposed by the second register trench (RT2).

According to the second embodiment, after etching so that a part of the register semiconductor layer (210B) is exposed by the second register trench (RT2), a register insulating layer (230) and a register poly layer (240) may be formed on the second register trench (RT2) (see FIG. 2A).

Accordingly, according to the second embodiment, after the register insulating layer (230) is formed on the second register trench (RT2) formed to a depth deep enough to expose a part of the register semiconductor layer (210B), a register poly layer (240) may be formed on the register insulating layer (230).

According to the second embodiment, the length of the poly layer (240) for the register can be maximized without causing an electrical short circuit by the insulating layer (230) for the register. Accordingly, there is a special technical effect that enables the implementation of ultra-fine semiconductor devices while implementing a high-resistance poly resistor.

Hereinafter, the manufacturing process will be described based on the structure of FIG. 4B (the second embodiment), but the embodiment is not limited thereto.

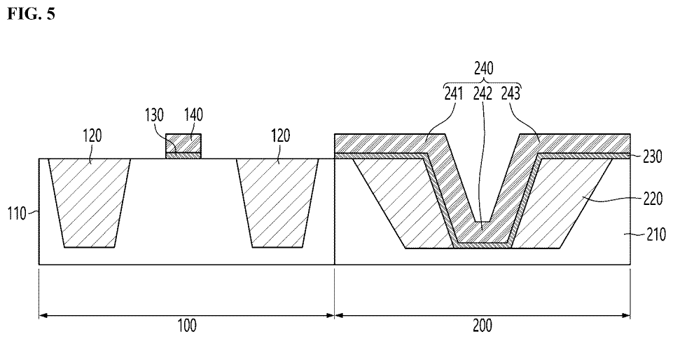

Referring to FIG. 5, a gate insulating layer (130) and a gate electrode (140) may be formed on the device semiconductor layer (110) located between the first isolation region of devices (120).

The gate insulating layer (130) may be formed as a thermal oxide layer or a deposition oxide layer, but is not limited thereto. The gate electrode (140) may be formed as polysilicon, but is not limited thereto.

The gate insulating layer (130) may be formed with a thickness of about 1,000 Å to 200 Å, but is not limited thereto.

At this time, a register insulating layer (230) and a register poly layer (240) may be formed on the second register trench (RT2) of the register semiconductor layer (210). The register insulating layer (230) may be formed of the same material as the gate insulating layer (130), but is not limited thereto.

The register poly layer (240) may include a trench poly layer (242) disposed inside the second register trench (RT2) and first and second poly layers (241, 243) disposed on the second isolation region of device (220), respectively.

According to the second embodiment, after etching so that a part of the register semiconductor layer (210B) is exposed by the second register trench (RT2), a register insulating layer (230) and a register poly layer (240) may be formed on the second register trench (RT2).

Accordingly, according to the second embodiment, after the register insulating layer (230) is formed on the second register trench (RT2) formed to a depth so deep that a part of the register semiconductor layer (210B) is exposed, a register poly layer (240) may be formed on the register insulating layer (230).

According to the second embodiment, the length of the register poly layer (240) can be maximized without causing an electrical short circuit by the register insulating layer (230). Accordingly, there is a special technical effect that enables the implementation of ultra-fine semiconductor devices while implementing a high-resistance poly register.

Meanwhile, a problem was studied in which a surface of the second register trench (RT2) may be roughened by a process of forming a second register trench (RT2) by etching the second isolation region of device (220) to a deep depth, and the roughness may be transmitted to the register poly layer (240) formed thereafter, thereby causing a change in the resistance of the resistor device.

According to an embodiment, after forming the second register trench (RT2), the surface of the second register trench (RT2) can be improved in roughness by a process of forming a register insulating layer (230), and thus, there is a special technical effect of preventing the occurrence of roughness in the register poly layer (240) formed thereafter, thereby ensuring a stable resistance value of the resistor device.

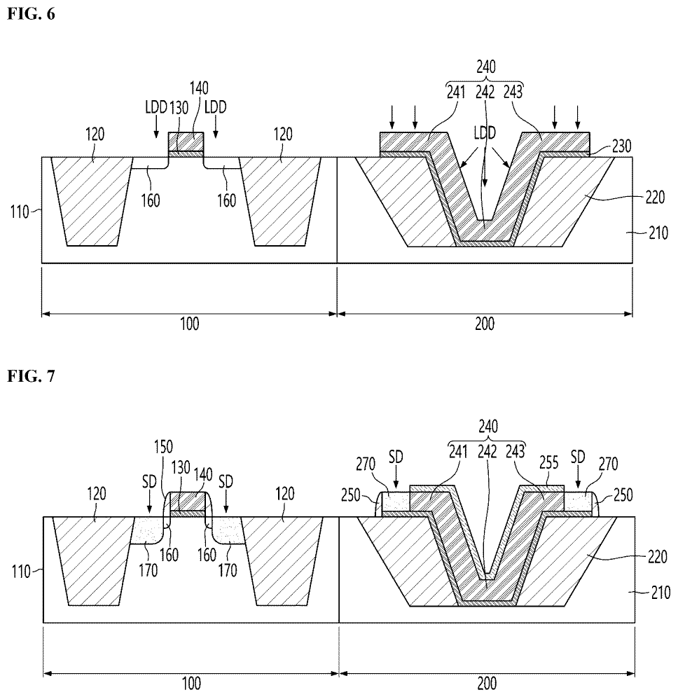

Next, referring to FIG. 6, a first ion implantation (LDD) may be performed on the device semiconductor layer (110) on both sides of the gate electrode (140) to form a first ion implantation region (160).

The device semiconductor layer (110) may be formed as an N-MOS region or a P-MOS region.

For example, after forming a p-type well (not shown) in the device semiconductor layer (110), an n-type dopant may be ion-implanted into the p-type well to form a first ion implantation region (160). At this time, LDD ion implantation may also be performed on the register poly layer (240).

Next, referring to FIG. 7, after forming a first spacer (150) as an insulating layer or the like on the side of the gate electrode (140) of the device semiconductor layer (110), a second ion implantation (SD) may be performed to form a source region (170) and a drain region (170).

The doping concentration of the second ion implantation (SD) may be higher than that of the first ion implantation (LDD), but is not limited thereto.

For example, the doping of the second ion implantation (SD) may be a high-concentration n-type dopant ion implantation process, and the high-concentration n-type dopant may be doped at a concentration of 5E15/cm² to 8E15/cm² while being injected with an energy of about 50 keV to 80 keV, but it is not limited thereto.

Meanwhile, after the second spacer (250) and the third resistor insulating layer (255) are formed on the register poly layer (240) on the register semiconductor layer (210), a register ion implantation region (270) may be formed by the second ion implantation (SD).

For example, after the second spacer (250) is formed on the first and second poly layers (241, 243) of the register poly layer (240) and the third resistor insulating layer (255) is formed on the trench poly layer (242), a register ion implantation region (270) may be formed on the first and second poly layers (241, 243) by the second ion implantation (SD).

The register ion implantation area (270) may be in contact with the register insulating layer (230), but is not limited thereto.

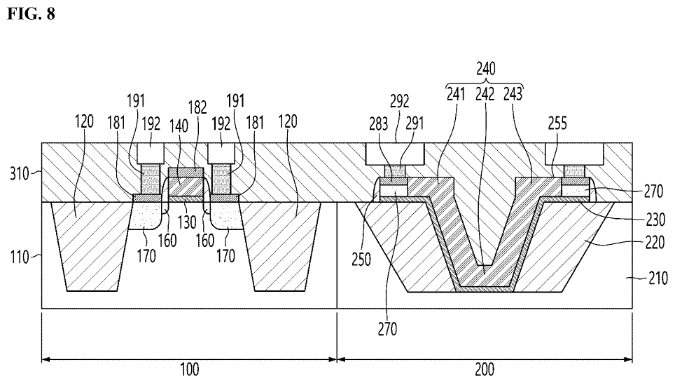

Next, as shown in FIG. 8, a first silicide (181) may be formed on the source region (170) and the drain region (170) of the device region. A second silicide (182) may be formed on the gate electrode (140).

A third silicide (283) may be formed on the register ion implantation region (270) of the register poly layer (240). The first to third silicides (181, 182, 283) may be NiSi or CoSi₂, but are not limited thereto.

After the interlayer insulating layer (310) is formed, an open process is performed to remove a portion of the interlayer insulating layer, and a first wiring (191) and a first metal electrode (192) are sequentially formed on the exposed first silicide (181). In addition, a second wiring (not shown) and a second metal electrode (not shown) are sequentially formed on the second silicide (182).

In addition, a third wiring (291) and a third metal electrode (292) are sequentially formed on the third silicide (283), thereby forming a semiconductor device having a resistance device according to the embodiment.

Although the above description focuses on the embodiment, this is merely an example and does not limit the embodiment, and a person having ordinary knowledge in the field to which the embodiment belongs will be able to understand that various modifications and applications not exemplified above are possible without departing from the essential characteristics of the present embodiment. For example, each component specifically shown in the embodiment may be modified and implemented. And the differences related to such modifications and applications should be interpreted as being included in the scope of the embodiment set forth in the appended claims.

What is claimed is:

1. A resistor structure of a semiconductor device comprising:
a semiconductor substrate including a device semiconductor layer and a resistor semiconductor layer;
a first isolation region of device and a second isolation region of device respectively disposed on the device semiconductor layer and the register semiconductor layer; and
a register poly layer disposed on a first register trench from which a portion of the second isolation region of device is removed.

2. The resistor structure of the semiconductor device of claim 1, further comprising a register insulating layer disposed under the register poly layer on the first register trench.

3. The resistor structure of the semiconductor device of claim 1, wherein the register poly layer comprises a trench poly layer disposed inside the first register trench and first and second poly layers disposed on the second isolation region of device, respectively.

4. The resistor structure of the semiconductor device of claim 1, wherein a first depth of the first register trench is at least ½ of a depth of the second isolation region of device.

5. The resistor structure of the semiconductor device of claim 1, wherein the resistor poly layer comprises a resistor ion implantation region.

6. The resistor structure of the semiconductor device of claim 5, wherein the resistor ion implantation region is in contact with the resistor insulating layer.

7. The resistor structure of the semiconductor device of claim 1, wherein a horizontal width of the second isolation region of device is greater than a horizontal width of the first isolation region of device.

8. The resistor structure of the semiconductor device of claim 1, wherein a depth of the first isolation region of device is the same with that of the second isolation region of device.

9. The resistor structure of the semiconductor device of claim 2, wherein a material of the register insulating layer is the same with that of a gate insulating layer.

10. The resistor structure of the semiconductor device of claim 2, wherein the resistor insulating layer is spaced apart from the resistor semiconductor layer.

11. A resistor structure of the semiconductor device comprising:
a semiconductor substrate including a device semiconductor layer and a resistor semiconductor layer;
a first isolation region of device and a second isolation region of device respectively disposed on the device semiconductor layer and the resistor semiconductor layer;
a resistor insulating layer disposed on a second register trench from which a portion of the second isolation region of device is removed to expose a portion of the resistor semiconductor layer; and
a resistor poly layer disposed on the resistor insulating layer.

12. The resistor structure of the semiconductor device of claim 11, wherein the resistor poly layer comprises a trench poly layer disposed inside the second register trench and first, second poly layers disposed on the second isolation region of device.

13. The resistor structure of the semiconductor device of claim 11, wherein a second depth of the second register trench is the same as a depth of the second isolation region of device.

14. The resistor structure of the semiconductor device of claim 11, wherein the resistor poly layer comprises a resistor ion implantation region.

15. The resistor structure of the semiconductor device of claim 11, wherein the resistor ion implantation region is in contact with the resistor insulating layer.

16. The resistor structure of the semiconductor device of claim 11, wherein a horizontal width of the second isolation region of device is greater than a horizontal width of the first isolation region of device.

17. The resistor structure of the semiconductor device of claim 11, wherein a depth of the first isolation region of device is the same with that of the second isolation region of device.

18. The resistor structure of the semiconductor device of claim 11, wherein a material of the register insulating layer is the same with that of a gate insulating layer.

19. The resistor structure of the semiconductor device of claim 11, wherein a second depth of the second register trench is greater than a thickness of the second isolation region of device.

20. A semiconductor device comprises the resistor structure of the semiconductor device of claim 1.
